(19) United States
(12) Patent Application Publication
(10) Pub. No.: US 2002/0009000 A1
(43) Pub. Date: Jan. 24, 2002

(54) Adding imperceptible noise to audio and other types of signals to cause significant degradation when compressed and decompressed

(75) Inventors: Paul R. Goldberg, Palo Alto, CA (US); Vlad Fruchter, Los Altos, CA (US); Mauricio Greene, San Francisco, CA (US); Sergiy Bilobrov, Coquitlam (CA); Jason Lesperance, Vancouver (CA); Dmitri Chmounk, Novosibirsk (RU)

Correspondence Address: SKJERVEN MORRILL MACPHERSON LLP, Three Embarcadero Center Suite 2800, San Francisco, CA, 94111, US

(73) Assignee: QDesign USA, Inc.

(21) Appl. No.: 09/854,166

(22) Filed: May 11, 2001

Related U.S. Application Data
(63) Continuation-in-part of application No. 09/667,345, filed on Sep. 22, 2000.
Application No. 09/667,345 is a continuation-in-part of application No. 09/570,655, filed on May 15, 2000.
(63) Continuation-in-part of application No. 09/484,851, filed on Jan. 18, 2000.
(63) Continuation-in-part of application No. 09/584,134, filed on May 31, 2000.

(51) Int. Cl. G11C 29/00

(52) U.S. Cl. 365/200

(57) ABSTRACT

Primarily in order to discourage compression of data of signals intended for interfacing with humans, such as those containing audio content, particularly music, and thus to discourage the unauthorized reproduction and distribution of such content, such as over the Internet, the signal data is modified in a manner that is normally not perceptible to humans when the signal is reproduced but which causes the signal to be significantly degraded in a manner that is perceptible if the signal is later compressed and decompressed. In one embodiment, an audio signal is modified directly in a manner that causes significant degradation of the signal if it is compressed and subsequently decompressed. In another embodiment, a compressed version of an audio signal is modified, as part of a process of compressing the signal, in a manner that allows a good quality signal to result from a subsequent decompression but which results in a significant, perceptible degradation if this decompressed signal is again compressed and decompressed.

### CROSS-REFERENCE TO RELATED APPLICATIONS

This is a continuation-in-part of co-pending patent application Ser. No. 09/667,345, filed Sep. 22, 2000, which in turn is a continuation-in-part of copending patent application Ser. No. 09/570,655, filed May 15, 2000. This is also related to patent application Ser. No. 09/484,851, filed Jan. 18, 2000, and its continuation-in-part application Ser. No. 09/584,134, filed May 31, 2000, hereinafter referred to as the “Secure Transmission Patent Applications.” These four applications are expressly incorporated herein by this reference.

### BACKGROUND OF THE INVENTION

This invention is related to the processing, transmission and recording of signals intended for interfacing with humans, particularly music and other audio signals, and, more specifically, to techniques that prevent or discourage the unauthorized copying and/or distribution of audio or other content of such signals.

The ease that music can be electronically distributed by private individuals over the Internet is causing great concern on the part of the music content providers, their distributors and retailers. It is now possible for one compact disc to be purchased and, in a matter of hours, electronically distributed by the purchaser without charge to his or her friends, and even to people or enterprises unknown to the purchaser. Clearly, this reduces the desire of many to pay for the music and causes great concern on the part of the recording industry that their revenues and profits are being significantly eroded. Record labels are reacting by employing all legal means to prevent this unauthorized copying and distribution, and by fostering the development of technological means to make this unprecedented delivery of free audio entertainment significantly more difficult or impossible.

What makes this electronic sharing of music over the Internet practical is the availability of high caliber audio compression algorithms. These algorithms are capable of reducing the data rates and data volumes, previously required to digitally represent music, by a factor of more than 10, while maintaining acceptable audio quality. The provider compresses the music data by such a factor and the recipient then applies a mating decompression algorithm to the received compressed data to recover something close to the original music. MP3 (MPEG 1 Layer 3) and AAC (Advanced Audio Coding) are examples of commonly used compression algorithms that offer this capability. DTS (Digital Theater Systems) and AC-3 compression algorithms are professionally used for movie sound tracks and the like. A common characteristic of these compression algorithms is that data of frequencies not separately resolvable by the human ear are discarded, thereby to reduce the amount of data necessary to be transmitted.

Psychoacoustic audio compression technologies, such as MP3 and AAC, operate by making quantized noise imperceptible to the human hearing system. In digital audio systems, such as those used by compact disks to deliver music to consumers, 16 bit resolution is considered to be about the practical minimum number of bits to use to keep the quantized noise down to an acceptable level (in this case about 96 dB below the maximum signal level). The objective of an audio compression algorithm is to use as few a bits as possible to represent the input audio signal. In order to use fewer bits, mechanisms need to be found to minimize the increased level of quantized noise, or make this higher level of noise indiscernible to the listener. The characteristics of the human hearing process provides several opportunities to do the latter. The first is the basic threshold of hearing. Human ears tend to be less sensitive at low and high frequencies. The second characteristic can be seen by considering the structure of the inner ear. The cochlea is a spiral, tapering passage with the basilar membrane that is stretched, more or less, across the diameter along its length. Sound is conducted from the outer ear to the fluid in the cochlea where it travels the length of the basilar membrane. Different frequency components of a sound vibrate the hair cells at different locations along the membrane, stimulating the auditory nerves. The frequency dependent movement of the hair cells make the ear act like a spectrum analyzer. A high level frequency component will not only vibrate the hair cells at the location sensitive to that specific frequency, but it will also vibrate the hair cells at some of the adjacent locations as well. The spreading of the response to a specific frequency over multiple hair cell sensors can and will override, or “mask”, the response to other lower level, nearby frequency components. The ability of relatively loud sounds to mask lower level ones is usually described by sets of frequency and level-dependent “masking curves”. If the quantizing noise produced by a coarse quantizer can be confined to the spectral region near to the signal component being quantized (or encoded), and if that noise is low enough to fall below the masking curve of the signal being coded, then the listener will not hear the quantized noise. That is, the amount of data that represent spectral regions near to the signal component being quantized can be reduced without it becoming noticeable to the listener.

What is needed is a means to permit this technology to serve the recording industry's need for revenue and profits, by allowing Electronic Music Distribution (“EMD”) to be used as another channel of distributing and collecting revenue for music product, while simultaneously preventing this same technology from negatively impacting the industry. The present invention is directed in large part to satisfying this need.

### SUMMARY OF THE INVENTION

Briefly and generally, an electronic signal that is perceptible to the senses of a human, such as an audio or video signal, is modified in a manner that is not perceptible until, after the signal is compressed and decompressed, the decompressed signal is noticeably degraded. The specific embodiments and examples provided herein relate primarily to the processing of audio signals but the principles used with audio signals also apply to other types of observed signals, such as video signals.

An audio signal is modified in a manner that is not perceptible to the human ear until, after compression according to one of various specific compression algorithms, an uncompressed version of the compressed signal is noticeably distorted to the human ear. The audio signal may be modified an amount that a small degradation is perceived by a limited number of trained observers but generally not noticed by ordinary listeners. It is the imperceptibility to ordinary listeners that is important, of course, not the perception of a relatively few number of audio experts. A subsequent compression and decompression of the modified signal then results in a reproduction of it that is perceived by ordinary listeners, as well as audio experts, to be significantly degraded. The original audio signal is modified so that its subsequent compression and decompression changes it from one that is acceptable to almost all listeners to one that is not acceptable to those same listeners. The perceptibility of the signal modifications can also be determined electronically by comparing the original and the modified signals with data of masking characteristics of the human ear that are in common use in sound signal processing, particularly as part of audio compression and decompresssion techniques.

In a first embodiment, the original audio signal is so modified, so that any such compression and decompression results in the distorted signal. In a second embodiment, a compressed audio signal is modified in a manner that provides a high quality signal when decompressed but which, when that decompressed signal is again compressed, its further decompression results in a noticeably distorted signal. The effect of providing a sound signal that cannot be compressed without such degradation of quality limits its distribution over the Internet since it is not currently practical to distribute uncompressed sound signal files over the Internet. The time taken to transmit uncompressed files and the computer storage space necessary to hold them are far too large for the usual Internet user. Therefore, illegal distribution of music over the Internet will be significantly reduced. Sales by music providers will be maintained.

In a first example of the first embodiment of the present invention, an audio signal is modified by increasing levels of its masked frequency components while still retaining those levels below the masking level of a typical human ear. The resulting distortion caused by this “anti-compression” processing of the signal is thus not heard by a listener. But when the modified audio signal is compressed and then decompressed by algorithms of the type discussed above, the resulting sound is significantly degraded in quality. This is because the compression algorithm is operating on a different sound signal than the original one that is desired to be reproduced. As a result, the masking levels are different and the reduced number of bits used to represent the spectrum are thus allocated differently. When these different bit allocations are used to reconstruct the sound signal, it does not represent the original signal. Indeed, the compression algorithm may need to allocate a limited number of bits to an expanded portion of the signal's spectrum, thus not representing the unmasked, audible portions with enough resolution. The resulting decompressed sound signal is a significantly degraded, noisy version of the original signal and is therefore not desirable for listening.

In a second example of the first embodiment of the anti-compression techniques, relationships between multiple audio data channels are used. The example of this embodiment employs the alteration of timing and or phase relationships found within an audio signal with two or more channels. Alteration of these relationships in a multi-channel signal causes subsequent compression and decompression processes to incorrectly combine the multiple channel data during the data reduction process, and thus cause a degraded version of the original audio signal to be produced after the compression process is complete.

A third example of the first embodiment of anti-compression techniques again uses relationships between multiple audio data channels. In this case, data from one channel of a multi-channel signal is added to the data of another channel of the multi-channel signal in a manner such that the donor signal is masked by the receiver signal. This data is altered in phase on a periodic or aperiodic basis and can also be altered in phase on a frequency component basis. The effect is to once again cause a subsequent compression and decompression process, which attempts to combine the data in the multiple channels as a strategy to reduce data rate, to incorrectly perform this combination process and thus cause the resulting compressed signal to be degraded when decompressed.

A fourth example of the first anti-compression embodiment once again uses the relationships between multiple audio data channels, but in this case they are used to unmask data embedded into the original signal that are masked by the audio data prior to the compression process being performed.

In a fifth example of the first anti-compression embodiment, it is noted that the mechanisms employed to reduce the data rate of monophonic and multi-channel signals often employ detectors which monitor input audio signals, partial results being available during the encoding process and/or included with the encoded output signal characteristics. The results of this monitoring activity are used to initiate different compression processing modes. These different modes are initiated in order to encode special case audio signals with fewer artifacts. The selection mechanisms driven by these detectors can and do make the wrong choices when encountering unanticipated changes in audio signal characteristics. When this occurs, an incorrect set of processing functions are employed to encode the incoming audio signal and the resulting encoded output signal does not accurately reflect the properties of the input signal. This fifth example of the first anti-compression embodiment takes advantage of this fact by placing phase, timing and/or amplitude discontinuities in the original signal, which are masked by the audio signal itself. These discontinuities cause the aforementioned detectors to switch to an incorrect mode with respect to the audio signal being processed, thus choosing an inappropriate processing function for the audio signal being encoded. Thus, when the encoded audio signal is decompressed, a compromised quality audio output is realized. These discontinuities can be monophonic in nature, in that a mode detector's confusion can be caused by discontinuities injected into only one channel of the data stream that are independently analyzed with respect to activity in other audio channels. They can also be multi-channel in nature, in that a mode detector's confusion can be caused by injected discontinuities which are analyzed in relationship to activity in one or more of the other audio channels.

In a second embodiment of the present invention, an encode/decode compression algorithm pair is described which has the characteristic of producing compressed audio data that can be decompressed for listening, but cannot be compressed with quality for a second time, thus effectively disallowing retransmission of the audio data over the Internet. A first example of this “one generation” codec with built in anti-compression processing, uses the addition of noise or other data to achieve the desired unique results.

A second example of the second embodiment employs the generational characteristics of compression algorithms to a similar end.

A third example of the one generation codec embodiment of the present invention uses the fact that compression algorithms with improved generational qualities often use additional techniques to reduce bit requirements without adding quantization noise. These techniques, Huffman encoding for example, form the basis of additional methods for producing compressed audio data that can be decompressed for listening, but cannot be compressed with quality for a second time. The unique concept, presented in this third example of the one generation codec, of embedding data within a compressed audio signal that is decoded by a subsequent decoding process as if it was part of the originally encoded data, and which is in a form that is compatible with the compressed audio data which comprises said compressed audio data stream, may be included as a central idea in all the examples of the second embodiment of the present invention.

In a fourth example of the one generation codec embodiment of the present invention, an alteration of the timing of the processing of defined blocks of audio data is employed to create a compressed version of the original audio data that displays high quality when decompressed and listened to, but will cause following compression and decompression processes to be unable to choose the size and process timing necessary to mask, transient noise added to the audio data during the initial compression process.

In a fifth example of the one generation codec embodiment, phase, timing and/or amplitude discontinuities are inserted into one or more of the channels of the encoded audio. These discontinuities are designed to be as imperceptible to the human ear as possible when they appear in the decompressed audio. However, they are tailored to cause the initiation of different compression processing modes in a subsequent encoding (compression) process, as described in the fifth example of the first anti-compression embodiment of this invention. The incorporation of these discontinuities in the codec allows for the discontinuities to be embedded in the encoded signal at the time of encoding, or the passing of discontinuity information from the encoder to the decoder by means of carrying the additional discontinuity data along with the encoded data stream in the data structure of the encoded signal. In the former case, discontinuities are added to the encoded, compressed audio data itself such that the decompression decoder will pass these discontinuities into the decompressed data stream without acting upon them, and thus these discontinuities will appear in the decompressed data stream with minimal or no alteration. In the latter case, the mixing of the discontinuities with the decoded data stream takes place in the decoder. This has two potential benefits. The first is to permit the original, unprocessed encoded data stream, to be recovered, if this should be desired. The second is to make it possible to convert existing multi-generational codecs, such as AAC and MP3, into single generation codecs, without the need to change the inner processing structure of these codecs. This is because the discontinuity data can be added to the decompressed signal after decoding. It should be noted that all previously described one generation codec examples can be implemented in this manner. It should also be noted that a decoder can be constructed such that the discontinuity data is generated within the decoder, with no discontinuity information passed to the decoder from the encoder. This discontinuity information is then derived from analysis of the signal characteristics of the decoded audio signal and mixed with the decoded audio signal before it is delivered to the user as a time domain audio output.

A unique method of adaptively optimizing anti-compression processing of audio data is also included as part of the present invention. For example, any of the foregoing processing techniques can be adjusted as a function of characteristics of the input audio signal being processed during such processing.

Finally, a unique concept is included that discourages, and makes it difficult for computer hackers compromise the beneficial effects of the audio processing begin disclosed.

In general, rather than using the principles underlying compression algorithms to reduce the amount of audio signal data while maintaining quality, the techniques of the present invention apply those principles to change the character of the sound signal so that it cannot be compressed without significant degradation in the quality of the signal. Indeed, existing compression algorithms have been designed to allow a signal to be compressed and decompressed two or more times without significant degradation of the quality of the signal that is perceptible to the human ear, termed their “generational” quality. But the present invention uses the principles of compression in a reverse manner, modifying a sound signal so that it will not retain its quality when compressed. This contrary use of the principles underlying compression algorithms greatly improves the ability of a music provider to control the distribution of its music.

Additional features, advantages and objects of the present invention are included in the following description of its embodiments, which description should be taken in conjunction with the accompanying drawings.

### BRIEF DESCRIPTION OF THE DRAWINGS

FIG. 1 illustrates the processing of an audio signal according to the present invention;

FIG. 2 is a curve representing an audio signal being processed;

FIG. 3 is an example frequency spectra for a block of the audio signal that shows its processing according to the present invention;

FIG. 4 shows an example frequency spectra for a block of the audio signal after it is modified by the processing of the present invention;

FIG. 5 illustrates a recording application of the present invention;

FIG. 6 illustrates an Internet music delivery application of the present invention;

FIG. 7 shows a key card for use in the delivery application of FIG. 6;

FIG. 8 illustrates a one generation codec with built-in anti-compression components as part of the compression process;

FIG. 9 illustrates the application of “adaptive processing”, referred to as optimization, to maximize the difference between the high quality of a processed but not compressed audio signal as compared with the reduced quality of a processed and compressed audio signal;

FIG. 10 shows a multi-channel audio compression encoding technique with which various aspects of the present invention may be used;

FIG. 11 illustrates a method of adding discontinuities to multi-channel audio signals;

FIG. 12 shows example frequency and phase characteristics of two channel audio anti-compression filters of FIG. 11;

FIG. 13 provides example two-channel audio signal characteristics and resulting compression algorithm encoding modes;

FIG. 14 includes waveforms before and after an example anti-compression processing according to an example of the present invention;

FIG. 15 illustrates anti-compression processing according to an example of the present invention; and

FIG. 16 is a block diagram showing a single ended one-generation encoding technique according to the present invention.

### DESCRIPTION OF EXEMPLARY EMBODIMENTS

First Embodiment: Audio Signal Anti-compression Examples

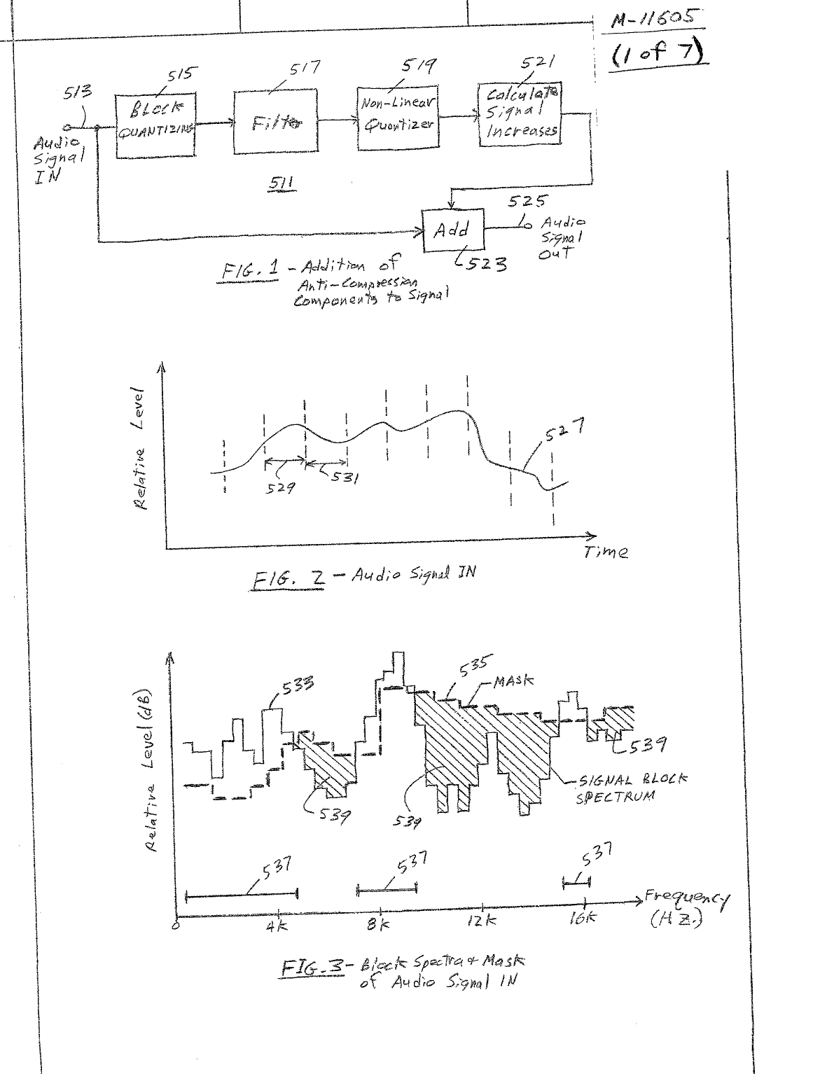

The block diagram of FIG. 1 shows an example anti-compression signal modification system 511 of the first embodiment of the present invention, which operates to process an input audio signal 513. The first three processing steps 515, 517 and 519 are substantially the same as those of a compression algorithm of the type discussed above. In the step 515, a block of data of the signal 513 is acquired. Referring to FIG. 2, a portion 527 of the signal is shown divided into time successive blocks, such as blocks 529 and 531. Preferably in a digital format, data representing samples of the signal 527 during a block are quantized in the step 515. The signal block is then filtered in a step 517 in order to obtain floating point coefficients of the frequency spectrum of the block of data. Each sampled frequency is expressed as an exponent (coarse measure) and mantissa (fine). Those values are then used by a non-linear quantizer 519 to calculate a masking function 535 (FIG. 3) and compare it to the spectrum 533 of the block. When used as part of a compression algorithm, the quantizer 519 also allocates a lesser number of bits than in the incoming signal 513 to represent the signal in limited frequency ranges 537 where the spectrum 533 is greater than the mask 535. The remaining frequency ranges are not necessary to be included in the compressed signal since they are below the levels indicated by the mask 535 that a human ear can hear. So they can be omitted, and it is this omission that allows the amount of data representing the signal to be reduced.

But since, in the technique being described, the input signal is not being compressed, the bit allocations for the limited frequency ranges 537 need not be calculated. Rather, a step 521 is added that does not exist in compression algorithms. This step calculates increases that can be made to various frequency components of the incoming signal 513. The block spectrum 533 and mask 535 calculated in the non-linear quantizer 519 are used in this calculation. This calculation increases the value of frequency components that are less than the mask 535, increasing the signal spectrum 533 into shaded regions 539 of FIG. 3. Since, as expressed by the masking function, the human ear cannot separately resolve these frequencies, this will not be perceived to degrade the signal, so long as the spectrum 533 is not increased above the level of the mask 535. Indeed, it is preferable to maintain the spectrum 533 below the mask 535 by some margin in the regions 539 to assure that these added signal components will not be heard by the human ear. Example margins are ten or twenty percent of the level of the masking function 535.

Furthermore, all frequencies in the regions 539 need not be raised above the levels of the curve 533. The spectrum 533 needs to be altered only enough to result in a subsequent application of a compression and decompression algorithm to the modified signal to cause undesirable perceptible distortions of the original signal 513.

And, as a further feature, the level of some frequency components of the signal 533 may be increased above the mask 535 without affecting the quality of the sound to the human ear, such as at frequencies adjacent peak frequency levels of the spectrum. This type of change to the signal 533 can also affect the ability of a decompression algorithm operating on a compressed version of the altered signal to provide a good quality decompressed signal.

Alternatively, changes to the spectrum 533 may be more modest so that the modified signal can be subject to one compression and decompression cycle without significantly degrading the quality of the incoming signal 513 but would result in serious degradation if again compressed and decompressed. This partial degradation has application to the Internet, wherein the partially degraded signal is initially sent over the Internet and re-transmissions of the audio signal are discouraged when the second or more cycle of compression and decompression makes the sound undesirable. This application is discussed below with respect to FIG. 8.

In any event, the additional calculated signal is then added to the input signal 513 at 523 in order to provide a modified signal output 525. An implementation of the processing of FIG. 1 includes a digital signal processor that operates under controlling software to perform the functions described above.

The step 521 may determine in one of several ways the amount that the level of the audio signal 513 is to be increased in the step 523 over a portion or all of the frequency ranges 531. One way is to generate random or pseudo-random noise that is uncorrelated with the signal 513 and add appropriate levels of such noise to the signal in the block 523. Another way is to generate a defined signal, such as a sine wave or a combination of sine waves of different frequencies, that is uncorrelated with the audio signal, and then add such a signal(s) to the audio signal.

A further way to modify the audio signal 513 is to add an amount of signal data that is correlated to it. This last technique may be implemented by simply increasing the levels of the frequency components already in the signal that are below the masking curve 535. This preserves the original audio qualities of the initial signal because the added data is correlated with that signal. The added data is then also difficult to distinguish from the original signal when listening to the resulting output audio signal 525. One way to increase the signal levels is to multiply the levels of some or all of the various frequency components of the audio signal 513 within the frequency ranges 539 by a frequency dependent factor greater than unity to increase the level of some or all of such frequencies to a level that is equal to or some defined amount below the masking function 535.

Yet another way to modify the audio signal of 513 is to add a replica of the original signal from one or more frequency bands, position shifted in time by one or more clock cycles with respect to the original audio signal, to the original audio signal. The original audio qualities of the initial signal are preserved because the added data is presented in very rapid sequence with respect to the original data and is correlated with the original audio signal. Here again, the added data is also difficult to distinguish from the original signal when listening to the resulting processed output audio signal 525. One way to add this replicated time shifted data is to store a block of the original audio signal's frequency domain coefficients, delay this coefficient data in time, recreate a time domain representation from the frequency coefficient data, and add this delayed time domain data back to the time domain representation of the original signal. Another way is to first use a narrow band filter bank in the time domain to separate the frequency components of the original signal into multiple narrow bands. Then select which frequency band or bands of the original audio data are most beneficial to replicate and delay by one or more clock cycles with respect to the original audio data, based on which one of these frequency components will require the most bits to accurately represent the original signal in a compressed version of the original signal. Then amplitude normalize these frequency components with respect to the original signal, such that their amplitude is above, equal to or below the masking curve amplitude defined by the frequency components of the original audio signal, based on the masking properties associated with each band of frequencies. Then time synchronize this frequency band data, and combine it with the original audio data. Subsequent compression of an audio signal processed in either of these manners is degraded because a compression algorithm will allocate additional bits to the added time shifted data in an effort to maintain the quality of the compressed audio.

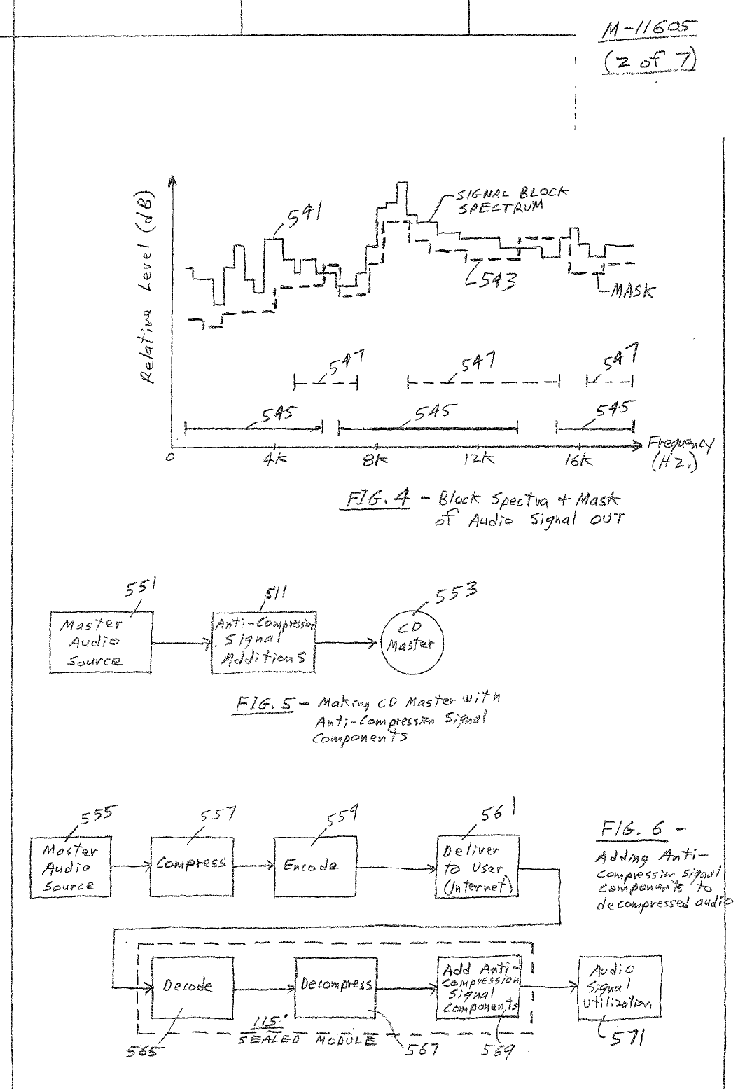

The curves of FIG. 4 illustrate the effect of one specific application of the signal processing described with respect to FIGS. 1-3. A frequency spectrum 541 is shown for a block of the output audio signal 525 in the same time interval as illustrated in FIG. 3. The input signal 513 has been modified by increasing the level of the spectrum 533 in all frequency ranges where it was below the mask 535 (shaded regions 539) up to the level of the mask 535. . This represents the maximum increase of the input signal 513 that is desirable, and, as discussed above, is normally more than what is normally prudent to add. The main point to note from FIG. 4 is that the output signal 525 now has a different frequency spectrum than the input signal 513. If the output signal is then compressed by the type of algorithm discussed above, a resulting mask 543 is different. The mask of a block is calculated as part of compression algorithms from the frequency spectrum of the block itself and, in some algorithms, from data of the frequency spectra of adjacent blocks occurring in time before and/or after the block represented by FIG. 4.

The example shown in FIG. 4 shows a large extent 545 of frequencies where the spectrum 541 is higher than the mask 543. The compression algorithm then must allocate its limited number of bits across the frequency bands 545 which are much larger in extent of frequency than the bands 537 (FIG. 3) of frequencies for the original signal 513. Further, the signal spectrum 541 (FIG. 4) of the output signal 525 is much different than the spectrum 533 (FIG. 3) of the input signal 513, differences being noted over ranges 547 of frequencies. At the same time, the increased signal has the effect of causing the signal spectrum 541 and the mask 543 calculated (at least in part) from it to follow each other more closely (curves of FIG. 4 vs. those of FIG. 3). This also makes the signal less compressible after the signal has been increased. The result is a compressed signal calculated from the output signal 525 that is much different than one calculated from the input signal 513. The output signal 525, because of the nature of the data intentionally added to the input signal 513, does not lend itself to compression if a faithful reproduction of the input signal 513 is desired upon decompression.

Like psychoacoustic based compression processes, the embodiment described above transforms the complex audio signals that are input to the system into the frequency domain, and masking curves for the different signal components are computed. The masking (hearing) threshold curves are compared with the spectrum of the input audio signal, and the limits on the level of quantizing noise or other added data that can be “hidden” by the audio signal input to the system is thus determined. In the compression processing case, the encoder then makes decisions about the coarseness of the quantizer, or the number of bits that need to be assigned to each of the frequency components of the audio signal, in order to assure that the added quantizing noise, caused by the coarser quantizing process, is masked and thus imperceptible to the listener. In the case of the techniques being described herein, however, this information is employed to determine how much extra noise, for example, can be added to the original audio signal input to the system, before this noise can be heard by the listener. Unlike the compression processing case, in which the output signal is the lower data rate, more coarsely quantized signal, the present techniques output the original signal with noise added on a frequency component by frequency component basis, the level of added noise chosen to be just low enough to be masked by adjacent frequency components in the original audio signal. The audio output signal then no longer has the uniform low level noise floor of the original input audio signal. Instead it has a dynamically changing, program dependent noise floor. If this digital audio signal is converted into its analog audio presentation and listened to, the added noise will properly be masked by the adjacent higher level frequency components in the signal, and thus not heard. If, however, this processed signal is fed into a compression encoder/decode process for Internet distribution, the additional quantizing noise caused by this following audio compression/decompression process will add to the noise injected into the audio signal by the techniques described above. The resulting audio signal will then contain a total noise which is over the masking curve limit, and thus the noise will be perceptible to the listener. These noise artifacts will make the compressed audio signal unsuitable for distribution over the Internet, which is an objective of the present invention. It should be noted that the injected “noise” can have a wide range of characteristics. These characteristics are chosen to be most annoying to the listener in the event the noise is made perceptible by a follow-on compression process.

In a second method, timing and/or phase relationships between two channels (a stereo pair) of an audio signal composed of two or more channels, are modified. This modification can be a fixed phase or timing change, or a phase or timing change that varies over time. In addition, the modified phase or timing relationship can be different for each audio frequency encountered in the original audio signal. This technique is designed to work best with “Intensity” stereo or “Coupled” multi-channel compression possesses. Intensity stereo and coupled compression processes are well know in the art. These methods combine input audio data from two or more channels above a predefined frequency, and retain only the intensity of the total energy appearing in each frequency band above this predefined frequency. In this approach the intensity envelope of the total energy is encoded on a frequency by frequency basis, and the amplitude of the signal in each channel is retained. This channel amplitude information is delivered separately in the encoded bit stream to the decoder, so that the decoder can parcel the monophonic intensity envelope to each channel based on the original amplitude of the signal that appeared in any particular channel. By altering the phase or timing of the information in pairs of these channels with respect to each other, before they are combined, common data appearing in each channel pair cancel, or partially cancel, during the combining process. This results in an output after the decompression process which varies in amplitude, quite unlike the original stereo audio signal. By this means, a degraded version of the original audio signal will be produced after the compression/decompression cycle, but, because human hearing cannot easily detect phase variations, the stereo audio will sound normal before the compression/decompression process.

A simple implementation of the above concept calls for advancing or retarding the phase of one channel with respect to the other by a predetermined number of degrees, for example 180 degrees, of all frequencies above a predetermined frequency. 1500 Hz has proven to be a good frequency to choose for this purpose. This process produces an audio signal which sounds identical to the original stereo audio signal, but will be degraded by a subsequent compression process which employs intensity stereo techniques. The resulting intensity stereo compressed and decompressed audio signal sounds very much as if it is emanating from an underwater source because of the amplitude variations introduced in the audio program material by complete or partial phase cancellation as described above. A similar effect can be produced if, instead of introducing 180 degree phase inversion above a predefined frequency, one of the two channels of the stereo audio pair being processed is advanced or retarded in time with respect to the other channel. This can be implemented in the digital domain by advancing or retarding one of these two channels with respect to the other channel by 1 or more bits.

A more advanced version of the above concept calls for modulating the timing and or phase of a particular frequency or frequencies. For example, a rate below or above the lowest or highest frequency the human ear can detect can be employed. Such a rate could be 1 Hz. The modulation would be imposed on one or more frequency component present in one channel of a stereo channel pair as compared to the other channel of the stereo channel pair. This phase modulation will not significantly affect the processed original stereo audio data, but, when the processed data is compressed and decompressed by the use of an intensity stereo compression algorithm, causes an audio output whose amplitude varies in time and is quite degraded. This degradation is caused by the varying phase cancellation of the data which is common to both channels.

In a third example of the first embodiment of anti-compression, relationships between two or more audio data channels are again used to create an audio signal that will cause a compression and decompression process, which attempts to combine data in multiple channels as a strategy to reduce data rate, to incorrectly perform this combination process during encode and thus cause the resulting decoded signal to be degraded when decompressed. In this technique, data from one channel of a stereo pair of a multi-channel signal is reversed in phase and added, in the frequency domain, to data in the other channel of the stereo pair. For clarity of discussion we will call one of these channels the “right” or “R” channel and the other channel the “left” or “L” channel. Any two channels of a multi-channel audio signal, that is an audio signal with three or more channels, can be designated for the purposes herein as the “R” and “L” channels. The use of “R” and “L” nomenclature refers to a two channel stereo music source solely to aid in visualizing the concept, but there is no intent to limit this technique to such a source. Care is taken to insert this cross-channel data in a manner such that the donor channel signal data is masked after insertion into the receiver channel and does not significantly affect the quality of the resulting pre-compressed audio signal.

There are three separate approaches to reach this objective. One, insert signals from the L channel into the R channel that are under the masking threshold of the L channel. Two, insert signals from the L channel into the R channel which are not under the masking threshold of the L channel, but under the masking threshold of the R channel. Three, insert signals from the L channel in the R channel that are under both the L and R masking thresholds. To further add to the post compression degradation of the resulting signal, the added L to R cross-signal can be reversed in phase on a periodic or aperiodic basis. To further increase the anti-compression effect, the reversed phase L signal can be periodically or aperiodically inserted and not inserted into the R channel. Additional anti-compression effects can be realized by reversing the phase of only some of the frequency components of the L signal that is added to the R signal. For example, the phase of every second or third frequency bin of the L signal can be reversed before the L signal is inserted into the R channel. Note that although this discussion has referred to the addition of L data in the R channel, this is for example purposes only. The technique is equally valid for the insertion of R data into the L channel.

A fourth method of modifying audio signal 513 once again uses the relationships between multiple audio data channels. In this case spurious data which is masked by the original audio signal is embedded into each channel of the original audio signal. This data is caused to be “unmasked” when the audio signal is compressed. One example of this approach is to first alter or totally reverse the phase of one channel of a stereo audio signal with respect to its other channel. This alteration in phase, which could be either fixed, varying in time, or applied periodically or aperiodically, could be implemented on frequencies which lie above a predetermined frequency, over a range of frequencies, or over one or more bands of frequencies. The spurious data is then added in phase into both channels. By choosing the spurious data such that it is below the masking threshold of the original audio signal, the spurious data will be inaudible when this now processed audio signal is reproduced for listening. However, if this signal is compressed, using an intensity stereo encoder and then reproduced for listening, the original stereo audio signal will be reduced in amplitude due to phase cancellation between the channels, while the spurious data will be increased in amplitude, due to phase addition. This will result in a reduced masking level and an increased spurious data level. It will then follow that the embedded spurious data will be above the lowered masking threshold and be audible to the listener.

A modification of the above strategy is to add spurious data, at a selected frequency or frequencies, continuously, periodically or aperiodically, to one channel of a stereo audio signal, phase shift this added data by 180 degrees, and add it to the second channel of the stereo audio signal. The intensity and frequency components of this added signal energy would be chosen to be below the masking threshold set by the audio data in each channel. Being 180 degrees out of phase the spurious data added to the two channels would additionally tend to cancel when reproduced either in free air, through speakers or through headphones, and thus be virtually inaudible to the listener. When the audio processed in this manner is encoded with a compression algorithm that sums the absolute values of one or more of the frequency components in each channel of said two channel audio signal in order to reduce the data rate requirements of the compressed signal, the absolute values of the embedded spurious signals in each channel will constructively add and the embedded spurious signals will become audible to the listener.

A fifth example of the first anti-compression embodiment takes advantage of compression strategies that detect characteristics of input and in-process audio data. These strategies modify their processing parameters, and/or approach, as a function of these detected characteristics. Audio data compression mechanisms that use different signal processing modes are employed by both monophonic and multi-channel encoders. Two examples of such audio compression strategies are “Middle/Side” or “M/S” stereo encoding, sometimes referred to as “Sum/Difference” stereo encoding, for compressing two channel audio signals, and “window switching”, which is used for monophonic as well as multi-channel audio data compression. U.S. Pat. No. 5,285,498, “Method And Apparatus For Coding Audio Signals Based On Perceptual Model”, of James D Johnston, describes these two approaches in detail and is incorporated in its entirety herein by this reference. These different modes are “switched in” when special case audio signals are detected in order to encode these signals with the least audio artifacts at the lowest data rate possible.

The selection mechanisms driven by these detectors can and do make the wrong choices when encountering unanticipated changes in audio signal characteristics. When this occurs an incorrect set of processing functions are employed to encode the incoming audio signal and the resulting encoded output signal does not accurately reflect the properties of the input signal. The present example of the first anti-compression embodiment takes advantage of this fact by inserting discontinuities into the original signal which cause the encoder to switch to an incorrect mode with respect to the audio data being processed. These discontinuities can be phase, timing, frequency, amplitude or other signal discontinuities. For instance, they can take the form of frequency components that have been added to or periodically removed from the original audio signal. Thus, when the encoded audio signal is decoded, a compromised quality audio output is realized. These discontinuities can be monophonic in nature. In this case, the mode detector's false analysis is prompted by discontinuities in a single channel of the audio data stream, without regard to activity in other channels of the audio data stream. They can also be multi-channel in nature. In this case the mode detector's confusion is caused by discontinuities which are analyzed in relationship to activity in one or more of the other audio data channels.

It has been found that human listeners are most disturbed by audio whose characteristics change over time. If the aforementioned discontinuity causes the encoder to permanently switch to a mode which is inappropriate for a particular input audio selection, for example a certain selection of music, the decompressed decoded output will indeed be degraded as compared to the original signal. However, this degradation will be displayed by the music from its inception to its completion and the listener may become accustomed to the sound quality. With the objective of the first embodiment of the anti-compression process being to deter consumers from compressing content in their music libraries, for example, and redistributing this content over the Internet, a continuous degradation may not provide the reduction in value required. Therefore, this example five of the first embodiment of anti-compression includes the unique concept of adding and removing the aforementioned discontinuities on a temporal basis in order to cause a compression encoder to switch between one or more inappropriate and one or more appropriate encoder modes throughout the portions of the audio which is so processed.

To illustrate the application of example five of the first anti-compression embodiment, switching between M/S “joint stereo” coding mode and R/L independent channel “discrete stereo” coding mode will be used. FIG. 10 is an illustrative embodiment of a M/S stereo encoder. Perceptual Model Processor 679 evaluates thresholds for the left and right channels. The two thresholds are then compared on a frequency subband basis. For example, the Right and Left input signals 669 and 671 respectively, could have been divided into 32 coder frequency bands. In each band, where the two thresholds vary between Right and Left by less than some amount, typically 2 dB, but not necessarily 2 db, perceptual encoder 673 is switched into the M/S mode by the action of line 681 becoming a “1”. In the M/S mode perceptual encoder 673 uses M and S as its source data instead of R and L. That is, the Right signal for that band of frequencies is replaced by the sum of the Right and Left channels divided by 2 or the Middle” signal, M=(L+R)/2, and the Left signal is replaced by the difference of the right and left channels divided by 2 or the Side signal S=(L−R)/2. Thus, encoded outputs 675 and 683 are derived from M/S data not R/L data. The actual amount of threshold difference that triggers this substitution will vary with bit rate constraints and other signal system parameters.

The above selection of either M/S or R/L modes is actually the choice between independent coding of the channels, mode R/L, or using the SUM and DIFFERENCE channels, mode M/S. This decision is based on the assumption that human binaural perception is a function of the output of the same critical bands at the two ears. If the signals are such that they generate a stereo image, then the choice of R/L coding is more appropriate. If the signals are similar then additional coding gains, that is either a maintaining of encoded audio quality at a lower data rate or the improvement of audio quality at the same data rate, may be exploited by choosing the M/S coding mode. A convenient way to detect the similarity of the two channels being encoded is by comparing the monophonic threshold between Right and Left channels. If the thresholds in a particular band do not differ by more than a predefined value, then the M/S coding mode is chosen. This mode is chosen because this situation most often occurs when the amplitude of the frequency components, which comprise both signals, are very similar. Otherwise the independent mode R/L is assumed. Note that associated with each band is a one bit flag that specifies the coding mode of that band and that flag must be transmitted to the decoder as side chain information. Also note that the coding mode decision is adaptive in time since for the same band it may differ for subsequent segments, and is also adaptive in frequency since for the same segment, the coding mode for subsequent bands may be different. An illustration of a coding decision is given in FIG. 13.

MPEG 1 Layer 3 (MP3) Version 1.0 audio compression encoder, developed by Fraunhoffer Gesellshaft IIS, which is used in the Opticom “MP3 Producer” Version 2.1 application, is an example of an audio compression encoder which employs M/S stereo techniques as described above. The Fraunhoffer MP3 audio encoder determines whether it should use the R/L or M/S mode on a frame by frame basis and will switch into M/S mode when the average of the monophonic thresholds between Right and Left channel subbands do not differ by more than a predefined value. Although the Fraunhoffer MP3 encoder evaluates and performs a threshold comparison the effect, as seen in the external behavior of the encoder, is that the encoder will assume the M/S mode when the average energy in the frequency components of the R channel is almost equal to the average energy in the frequency components of the L channel. When the average energy of the frequency components in the R and L channels differ by more than a certain amount, then the encoder will go into the R/L mode. When the average energy of the frequency components in the R and L channels vary around this predefined level the Fraunhoffer MP3 encoder can become confused and toggle between the M/S and R/L modes. This uncertainty is exploited in this fifth example of the first anti-compression embodiment.

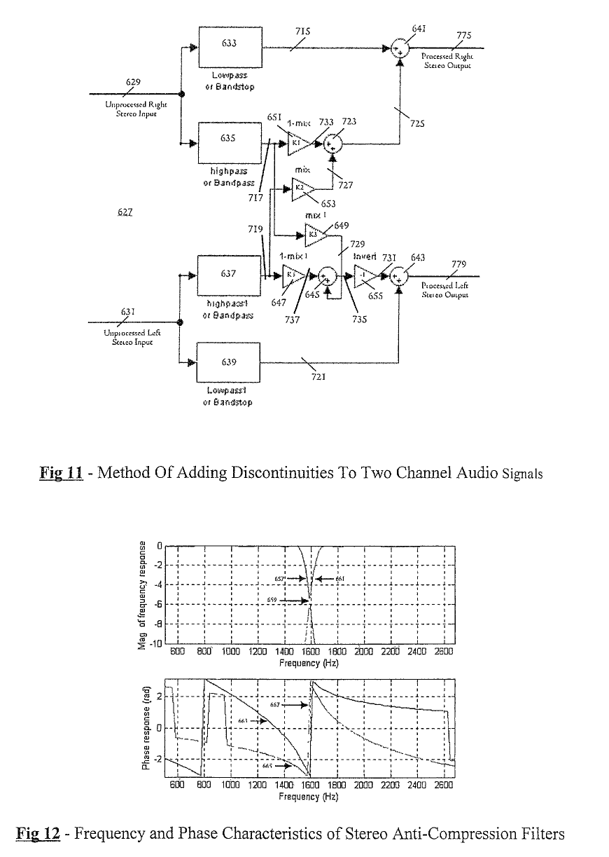

FIG. 11 is a block diagram of an implementation of the fifth example of the first anti-compression embodiment. It depicts the addition of phase and amplitude discontinuities to a stereo audio signal. As will be shown, these discontinuities cause the MP3 encoder, which follows the anti-compression processor depicted, to be uncertain as to the choice of M/S or R/L mode. This results in switching between these modes during the process of encoding the stereo audio signal. As shown in FIG. 11, which depicts anti-compression processor 627, Right channel input signal 629 and Left Channel input signal 631 are divided into low and high pass signals by passing them through respecive filters 633, 635, 637 and 639. This results in Right channel high pass signal 715, Right channel low pass signal 717, Left channel high pass signal 719 and Left channel low pass signal 721. Ignoring for the present the processing performed by the network composed of 647, 645, 649, 653, 651, and 723, Left channel high pass signal 719 is further processed by the 180 degree phase inverter 655 and added to the Left channel low pass signal 721 in mixer 643. This 180 degree phase inversion is not included in the processing chain for Right channel high pass signal 717 which is added to Right channel low pass signal 715 in mixer 641. Low pass filter block 633, high pass filter block 635, high pass filter block 637 and low pass filter block 639 serve to add phase and amplitude discontinuities around a predefined frequency. In the implementation shown, this frequency has been chosen to be approximately 1600 Hz. Note that 1600 Hz has been chosen for illustrative purposes only and could have been chosen to be any frequency above or below 1600 Hz. How effective the chosen frequency will be depends on the audio signals being processed. The phase and amplitude characteristics of these filter blocks are shown in FIG. 12.

Of course, the exact characteristics of these discontinuities will be dependent on the filter characteristics chosen and how the falling slopes of the low pass filters and the rising slopes of the high pass filters are related. In the implementation depicted, the falling slopes of low pass filters 633 and 639 and the rising slopes of high pass filters 635 and 637 have been chosen to be quite sharp, about 60 dB per octave, and their cross over point 659 has been chosen to be −6 dB from the flat portion of the filters frequency response. This selection of filter characteristics are for a specific example only. Other filter characteristics can alternatively be chosen. However, this set of characteristics will cause the frequency spectrum discontinuities injected into the Right and Left signals to assume minimum audibility in the uncompressed Right and Left stereo signal. They also can cause the M/S-R/L selection determination in the subsequent MP3 encoder process to be uncertain. As can be seen from FIG. 12, low pass filter falling slope 657 causes an amplitude dip in both the Right and Left Channels that begins at about 1500 Hz, before the high pass filter rising slope 661 has an opportunity to compensate for this loss in signal energy. Also, FIG. 12 depicts rapidly changing nonlinear phase responses 665 and 669 which culminate at an inflection point 667. This inflection point occurs at approximately 1600 Hz. When the R and L signals 629 and 631, respectively, are passed through this processing, by being separated into high and low bands and individually recombined through the action of mixers 641 and 643 respectively, these rapidly occurring, non-linear, amplitude and phase changes, centered around a 1600 Hz frequency, recombine in a constructive and destructive manner and result in transient changes in amplitude in processed Right Channel 775 and processed Left Channel 779 of FIG. 11. In the case of processed Left Channel 779, because of the action of inverter 655, these transient changes in amplitude are shifted in phase and therefore assume different amplitudes and timing as compared to the transients which appear in processed Right Channel 775.

If the average thresholds of the Right and Left Channels of a musical selection, which is to undergo Anti-Compression processing, are either solidly within the predetermined threshold difference band defined by a subsequent MP3 encoding process, or are substantially outside this difference band, the addition of the above described transients may be insufficient to cause the MP3 M/S-R/L analysis and detection mechanism to become confused and switch between M/S and R/L modes. If the Right and Left average thresholds are within this difference band, the MP3 encoder would remain in the M/S mode. If they are substantially outside this difference band, the MP3 encoder would continuously assume the R/L mode. Thus, it is preferred that a narrow threshold band be maintained between the channels in order to add Anti-Compression characteristics to the input audio signal, using the example Anti-Compression processing scheme. This situation is resolved by the cross channel mixing processing network composed of circuit blocks 647, 645, 649, 653, 651, and 723 of FIG. 11. For the MP3 encoder in this example, which chooses either the M/S or R/L mode depending on the difference between the average threshold derived from the thresholds of each coder frequency band in each channel, this network is adjusted such that the difference between the average thresholds of the Right and Left channels are forced to reside in the range of M/S-R/L switch uncertainty, where the MP3 encoder will switch between the two modes if the thresholds of the music varies. Natural variations in the Right and Left channel thresholds of the music being encoded will cause this to occur.

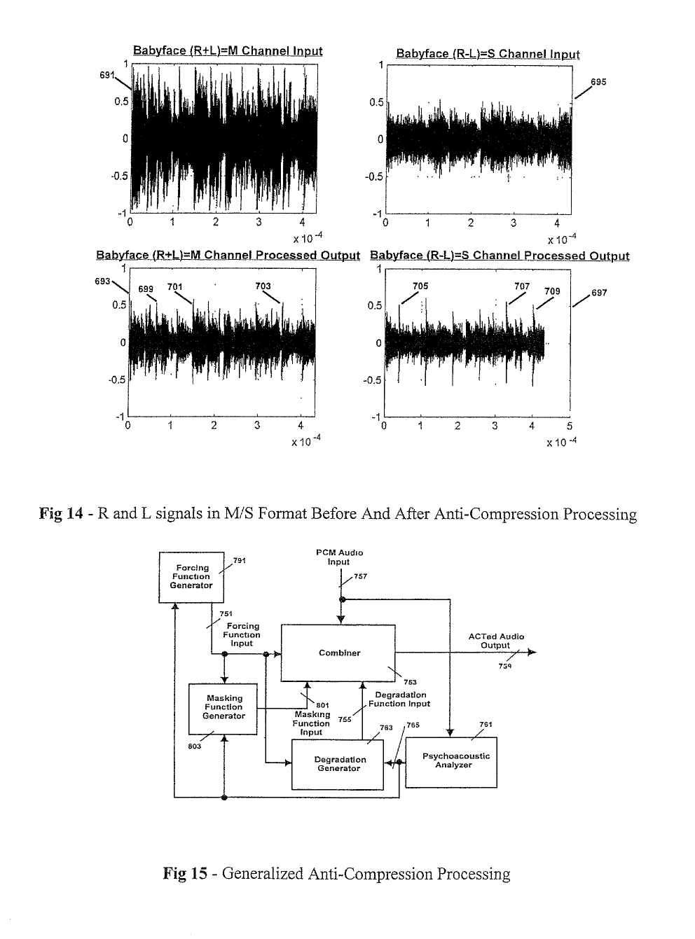

The effect these transients changes have on the MP3 encoding process are best visualized when the processed R and L signals, 775 and 779, respectively are converted to M and S signals. Recall that M (R+L) and S (R−L). FIG. 14 depicts M and S signals, associated with a musical selection called Babyface, before and after Anti-Compression processing 627 shown in FIG. 11. Original M and S input signals 691 and 695, respectively, are processed by Anti-Compression processor 627 into M and S output signals 693 and 697 respectively. Note transients 699, 701, 703, 705, 707 and 709. It is these signal discontinuities, which are directly derived from the Anti-Compressed Right and Left Channel signals, that cause the MP3 process to be uncertain as to the mode it should be in. Also note that if the MP3 encoder was to stay in one mode, the level of disturbance to the listener, caused by the action of the Anti-Compressed signal on the MP3 encoder, would be much lower, than if MP3 encoder continually switched between modes. It for this reason that audio quality modification, along with audio quality variation, are both unique characteristics of an Anti-Compressed audio signal that has undergone subsequent audio compression encoding and decoding.

The methods and apparatus associated with the implementation of the first embodiment of the present invention are generalized with respect to FIG. 15. An audio signal 757 is inputed to a Combiner 753 and a Psychoacoustic Analyzer 761. The Psychoacoustic Analyzer 761 determines the acoustic elements that comprise input audio signal 757, in terms of both spectral components and the timing of these spectral components, and inputs this data, which appears on line 765, to a Degradation Generator 763, a Forcing Function Generator 791 and a Masking Function Generator 803. The Degradation Function Generator 763, Forcing Function Generator 791 and Masking Function Generator 803 all employ the data on line 765 to create signals 755, 751 and 803, respectively, that are combined with the original audio signal in the Combiner 753. A degradation function Input 755 is created such that it is minimally audible in the Anti-Compressed audio output appearing on line 759, but, following a compression process, is perceptible in the decompressed version of this signal. A Forcing function Input 751 is also created such that it is minimally audible in the Anti-Compressed audio output appearing on line 759, but in this case the objective is to force audio compression encoding processes, which subsequently acts on the Anti-Compressed audio output 759, to employ encoding techniques or parameters during the encoding process that are inappropriate for the proper encoding of the Anti-Compressed audio output 759. Masking Function Input 801 serves the purpose of reducing the audibility and/or increasing the acceptability of the additional signals added to the input audio data stream by the Forcing Function and/or Degradation Functions generators. Note that the Forcing function 751 is also input to the Degradation Generator 763 and the Masking Function Generator 803. Therefore, in addition to causing an audio compression encoder to be uncertain as to what mode it should employ for encoding the Anti-Compressed audio signal appearing on line 759, or be forced into an inappropriate mode for encoding the Anti-Compressed audio signal appearing on line 759, Forcing function 751 also provides timing information to Degradation Generator 763 and Masking Function Generator 803. This permits the Degradation Function 755 and the Masking Function 801 to be inserted in the Anti-Compressed signal 759 at the time or times during which they will be most effective in causing the desired effect. In the case of the Degradation Function 755 this time or times are chosen to cause the Degradation Function to be audible after a compression-decompression cycle and non-offensive in the Anti-Compressed (ACTed) output signal 759. In the case of the Masking Function 801, this time or times are chosen to reduce the audibility of the Degradation Function and/or the Forcing Function in ACTed Audio Output 759.

Two items should be noted. First, it is sometimes unnecessary to include a separate Degradation Function and a separate Masking Function in Anti-Compressed output signal 759 in order to achieve the desired effect after a compression-decompression cycle. The act of a Forcing Function placing the audio compression encoder into a mode which is inappropriate for the proper processing of the original audio signal, can, by itself, be sufficient to cause the decoded decompressed version of the original audio signal to display the desired degradation. If the Forcing Function is sufficiently inaudible to the listener not to be distracting, the addition of a separate Masking Function would be unnecessary. Second, the Masking Function could be perceivable by a human listener, listening to an audio reproduction of the ACTed Audio Output 759, and still be acceptable. This case would occur if the Masking Function added to 759 is chosen to complement the artistry of the music signal appearing on 759. Such would be the case if the Masking Function was chosen to be, for example, a synthesized or naturally occurring trumpet sound that contained frequency components of the appropriate amplitude to mask the audibility of the inserted Degradation and/or Forcing Functions, and said Masking Function was inserted into an appropriate musical passage.

The processing elements defined in the generalized Anti-Compression process depicted in FIG. 15 are often encountered as compound elements that perform one or more of the Anti-Compression processing functions. For example, in the case of the fifth example of the first Anti-Compression embodiment depicted in FIG. 11 it can be seen that forcing function 751, produced by Forcing Function generator 791 of FIG. 15, is created by the actions of the Low Pass Filters 633 and 639 and the High Pass Filters 635 and 637. These elements add the temporal and spectral discontinuties that are desirable to cause a subsequent MP3 encoding process to switch between M/S and R/L modes. Thus they provide the forcing function required to cause audio compression encoder mode uncertainty. It can also be seen that the Degradation Generator function 763 of FIG. 15 is provided by the Inverter 655 of FIG. 11. This element causes spectral content above the 1600 Hz inflection point to destructively add during the creation of the M signal (M=R+L) when the MP3 encoder process is in the M/S mode, thus causing a loss of high frequencies in the M signal. It also causes spectral content above 1600 Hz to constructively add during the creation of the S signal (S=R−L, S=R−(−L), S=R+L) when the MP3 encoder process is in the M/S mode. Since in the M/S mode, the MP3 encoder provides the majority of the bits to the M signal, and the M signal has been degraded above 1600 Hz, the resulting decoded M and S signals will provide R and L signals that do not display the same high frequency characteristics as the original Anti-Compressed R and L signals appearing on lines 775 and 779 of FIG. 11. Thus it can be seen that the Inverter 655 serves the same purpose as the Degradation Generator 763 of FIG. 15. In addition, the function of the Combiner 753 of FIG. 15 is provided by adders 641, 643, 645, and 723 of FIG. 11. The only function provided for in FIG. 15 and not present in FIG. 11 are those of the Psychoacoustic Analyzer 761 and the Masking Function generator 803. These elements, which enhance the Anti-Compression process, are not included in the simple implementation of example 5 of the first Anti-Compression Embodiment.

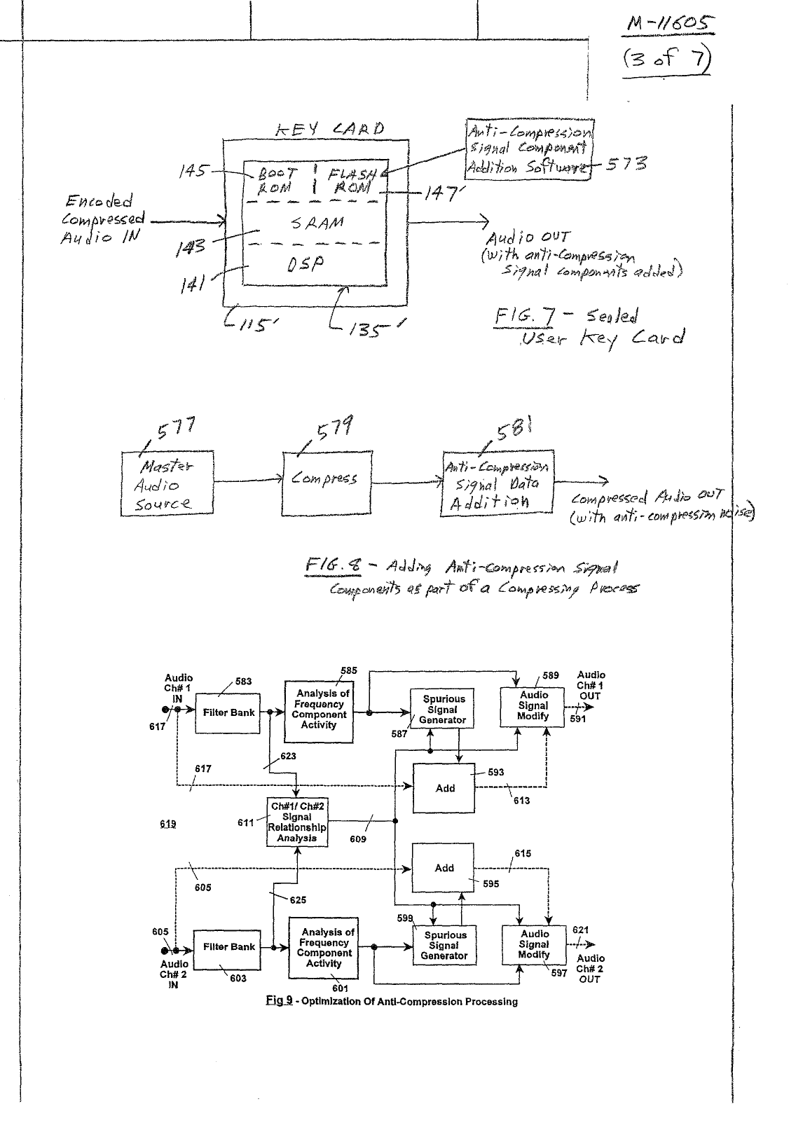

One important application of the signal modification system 511 depicted in FIG. 1 is illustrated in FIG. 5. After the music or other program material for reproduction on a Compact Disc (“CD”) is assembled as a digital file, indicated by a block 551, that file is processed by one or more of the techniques described above to add signal data to the audio signals of the file before making a CD master recording 553 from it. The content of the resulting replica CDs that are sold to consumers cannot then be compressed without a significant loss of quality of the content signals when decompressed. The same techniques can also be used when storing or distributing audio content by other means such as with audio tape, as a component of a Digital Video Disc (“DVD”), or as the digital or analog sound track on a motion picture release print. Since such compression is currently required before the audio content can be stored or distributed in several ways, such as storing in non-volatile semiconductor memory cards or transmission over the Internet or other communications network, unauthorized copying and distribution of the content is thus greatly discouraged. The degraded music or other audio content is of little value.

The block diagram of FIG. 6 illustrates a use of the present invention in the distribution of music or other audio content over the Internet in a manner that greatly discourages copying and re-distribution of the content by the recipient over the Internet. A master audio source file 555 is compressed, as indicated by a block 557, and then encoded, as indicated by a block 559, in order to provide a secure transmission that can be decoded only by the intended recipient. The compressed and encoded digital signal is then transmitted over the Internet 561 to the intended recipient who, in the normal case, has paid the content provider for it. The recipient must then decode the incoming signal, as indicated by a block 565, by use of a key or other accepted technique, and then decompress it, as indicated by a block 567. At this point, however, the master audio source file 555 is available to the recipient in a decoded and decompressed form that can easily be distributed to others over the Internet by a recipient who is willing to violate the copyright of the content provider. But since such unauthorized distribution is practical only if the content file is first again compressed by the recipient, noise or other data is added to the decoded and decompressed content file by the recipient's audio player or other utilization device, as indicated by a block 569. The recipient can, however, reproduce the audio content without degradation after the audio signal has been modified. The content, in the form of an analog or pulse code modulated (“PCM”) signal, for example, is applied to standard audio circuits 571 that drive a loud speaker or head phones.

Such a signal addition in the recipient's utilization device is made effective when the recipient has no effective choice but to receive an output of the content from his or her utilization device after the audio signal has been modified. In order to prevent the recipient from accessing the content signal before the signal is modified in the step 569, the signal modification is preferably performed in a physically sealed module 115′ that also includes the decoding function 565. A key necessary for decoding the signal is included within the module in a manner that renders it inaccessible to the recipient. Since the content provider can make it a condition of supplying the music or other content that the recipient use such a sealed module to decode the transmitted encoded content, the added security against the recipient being able to easily redistribute the audio content is conveniently included in the same sealed module. As can be seen from FIG. 6, a decoded digital signal of the content is not available except within the sealed module 115′. An input to that module is an encoded signal which the recipient cannot decode except with use of the module. An output of the module 115′ presents the content in a standard format, such as an analog or PCM signal, which could normally be re-digitized or otherwise manipulated by the recipient for unauthorized redistribution. But since such redistribution normally requires that the signal be compressed prior to doing so, the noise or other data that is added to the output signal by the processing step 569 makes that highly undesirable or even impossible.

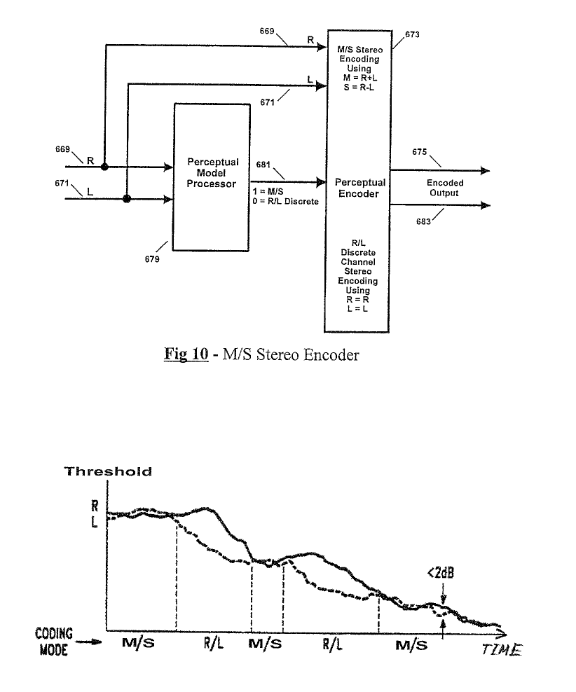

The sealed module 115′ is a variation of the module 115 described in the aforementioned Secure Transmission Patent Application, with a specific version shown in FIG. 7 hereof, where the reference numbers are the same as used in the Secure Transmission Patent Application but with a prime (′) added for corresponding elements that are modified herein. The primary, and perhaps only, component of the sealed module 115′ is a digital signal processor (“DSP”) integrated circuit chip 135′. The primary difference here is the inclusion of signal modification software 573 in its non-volatile memory 147′ in a manner that the user cannot access that software or defeat its use to add the anti-compression noise or other data before an audio signal is made accessible to the user (recipient) at an output of the module.

As described in the Secure Transmission Patent Applications, the module 115′ is preferably implemented in the form of a small key card that is made personal to a particular user by storing decryption (decoding) key(s) in its memory 147′ that are unique to the user. The key card is removably inserted into the user's audio player when connected to the Internet, a kiosk in a music store, or other content providing device, in order to purchase content from a provider with use of the user's key(s) stored within the card. The key card is also inserted into the recipient's player, as well as others, in order to allow the received content to be played by the recipient while restricting the extent to which the content can be transferred to or played by others. By the controlled addition of noise or other data to the content signal output of the sealed key card, according to the techniques described herein, unauthorized distribution and use are further technically restricted.

Second Embodiment: Allowing one Compression and Decompression of an Audio Signal

FIG. 8 shows a second embodiment of the present invention. In this second embodiment an encode/decode compression algorithm pair is described which has the characteristic of producing compressed audio data that can be decompressed for listening, but cannot be compressed with quality for a second time, thus effectively disallowing retransmission of the audio data over the Internet. A compression algorithm with this characteristic is called a “one generation” algorithm. The use of a one generation algorithm serves as an alternative to including anti-compression signal modification in the recipient's player, as described with respect to FIG. 6 and 7. As depicted in FIG. 8, an audio source file 577 is compressed with an available algorithm, as indicated by a block 579, and some noise or other data for the same purpose is added, as shown by a block 581. The amount that the audio signal is increased by 581 is below that which significantly affects the quality of the content when decompressed by the user. But it is sufficient to cause the quality of the content signal to be significantly degraded if the decompressed signal is again compressed with the type of algorithm described previously. In either of the versions of the first embodiment shown in FIGS. 6 and 7 or that of the second embodiment shown in FIG. 8, electronic distribution of music or other content is facilitated. It should be noted that the block 581 can be combined with the block 579 to form a single stage compression algorithm which provides a compressed audio output with anti-compression signal components added. In this case, a “calculate signal increases” block, such as block 521 of FIG. 1, and an “adder” block such as block 525 of FIG. 1, would be incorporated into the compression algorithm itself, following the compression algorithm's non-linear quantizer block and preceding the compressed audio output from the compression algorithm.

A second approach applicable to the one generation codec embodiment described above employs the fact that compression algorithms inherently add quantization noise to the original signal during the compression process itself. As previous described, this is due to the fact that individual frequency components of the signal are more coarsely digitized in an effort to reduce the number of bits used to described the signal. This leads to “generation loss” when “cascading” compression processes. When compression algorithms are cascaded, that is a signal is compressed, then decompressed and then compressed and decompressed once again, the resulting signal is naturally noisier than the original signal. The second embodiment of the present invention can take advantage of the mechanisms that produce generational loss, by employing those techniques that inherently modify the signal. These mechanisms can be used to naturally produce an output that, for example, has embedded noise which is very close to the masking thresholds depicted in FIG. 3. Such a result could be obtained by employing a non-linear quantizer in the compression algorithm that is adjusted to more coarsely quantize the individual frequency components of the signal. Thus, this output signal would not be able to undergo a second compression/decompression cycle without the added noise from the second compression cycle being above the masking threshold, and thus being audible in the output signal.

A third approach to implement the second embodiment of the present invention uses the fact that compression algorithms with improved generational qualities often use additional techniques to reduce bit requirements without adding quantization noise. These techniques can provide the basis for further one generation functionality methods. For example, some algorithms, such as the Dolby AC-3 compression algorithm, employ a technique called Huffman encoding in addition to reduced quantization resolution on a frequency band by frequency band basis. Huffman encoding uses the elimination of redundancies in the audio signal over time to reduce data requirements. It decreases the number of bits needed to described an audio signal by first encoding the audio signal using complete information and then only using differences in this information to describe the audio signal over a defined sequential time interval. Compression algorithms using such a technique have better generational characteristics than those that do not because they can use finer frequency band quantization and still maintain the desired compression ratio. They suffer, however, from having reduced audio data time resolution. The underlying assumption that significant changes in input audio signal characteristics will not take place over the time window used by the Huffman encoding process, can be used by the one generation compression process. One example of such use is the addition by a one generation audio compression process of short duration audio data or noise bursts to its output audio data stream. It is well known in the art that as an audio data sample is reduced in duration it must be of greater amplitude to be perceived by the listener when in the presence of competing sounds. For example, an 8 kHz tone with a duration of 1 millisecond, beginning 2 milliseconds after the initiation of 60 db of Uniform Masking noise, must be 33 dB greater in amplitude as compared to an 8 kHz tone with a duration of 20 milliseconds, beginning 2 milliseconds after the initiation of 60 db of Uniform Masking noise, to be perceived by the human ear. This was reported by H. Fastl in 1976 in his paper ‘Temporal masking effects: I. Broad band masker’ which appeared in Acustica, 35(5), 287-302. Audio data samples which occur randomly in time, or at chosen predetermined time intervals, and are short enough in time duration will therefore not be easily sensed by the listener, but will be detected by an audio compression process attempting to compress the audio signal. Using some of the specific techniques described above, as exemplified in FIGS. 3 and 4, will further hide the randomly added audio samples from a listener. If this audio compression process employs Huffman encoding, these pulses will asynchronously occur at the time the Huffman encoding process is preparing the data which is used as the reference for subsequent audio difference samples, and cause these subsequent samples to incorrectly represent the audio being compressed. In the case of Dolby AC-3, the Huffman encoding window is 30 milliseconds. This means that the output compressed audio will be corrupted for 30 milliseconds each time the Huffman reference information is spuriously altered by these embedded short audio noise bursts. This corruption will represent a significant degradation of the decompressed audio signal.

From the previous paragraph, the addition of embedded short noise bursts can be used to anti-compress an audio signal that has not been previously compressed. Any compressed and subsequently decompressed version of an audio signal that has been anti-compressed in this manner will thereby be degraded as compared to the original audio signal. By adding the frequency domain equivalent of these short noise bursts to, for example, the MP3 compressed version of an audio signal, these bursts will be decoded by a subsequent MP3 decoder as if they were part of the original signal. Since, as previously described, these noise bursts were masked by the original signal, the presence of these noise bursts in the decoded version of this encoded audio stream will be difficult to detect. However, if this decoded audio data stream is once again subjected to a compression encoding process, these bursts will cause the disruption in audio encoding function previously described, and the decompressed output from this recompressed audio stream will be degraded as compared to the original decompressed audio signal. Keep in mind that in the case of the first decoding of the compressed audio stream, the noise bursts have been added after all compression processing has been completed, and therefore the noise bursts have not disrupted any of the compression processing employed. However, in the case of the second decoding, the noise bursts were part of the audio signal being compressed and therefore disrupted the audio compression encoding process as previously described. It is for this reason that the subsequent decoded audio stream from this recompressed data stream is degraded. It is important to point out that although this example employs noise bursts as the means to cause audio compression encoder misbehavior, any of the anti-compression techniques discussed in this disclosure could be used. The unique concept of embedding data within a compressed audio or video signal that is decoded by a subsequent decoding process as if it was part of the originally encoded data, and which is in a form that is compatible with the compressed audio or video data which comprises said compressed audio or video data stream, is a fundamental part of the one-generation codec idea that comprises the second embodiment of the present invention.

As previously illustrated, some of the specific techniques described add sufficient noise to an audio signal at various frequencies and amplitudes to adversely affect application of a subsequent compression algorithm, but not enough to discernibly affect the quality of the signal without such further compression. A fourth approach applicable to the one generation algorithm of the second embodiment of the current invention shown in FIG. 8, uses a different method of accomplishing similar ends. It employs the concept of temporal unmasking. As described above, a usual compression encoding algorithm operates on successive, uniform blocks 529, 531 etc. of digital samples of the signal 527 (FIG. 2). If these blocks are not uniform, information defining the timing and number of bytes of data associated with each of these blocks of digital samples must be sent along with the compressed data for use by the compression decoding algorithm in order to reconstruct a replica of the signal 527. It is the alteration of this block timing and block size that can constitute the noise or data added by block 581 in the embodiment of FIG. 8, either alone or in combination with some level of spectral alteration.

In one popular compression process, each successive block of audio data includes 256 new time samples as well as the previous 256 time samples. This block of 512 overlapping samples is windowed and the data in this window, which moves in time, is transformed into 256 unique frequency coefficients. In addition, the input signals are analyzed with a high frequency bandpass filter, to detect the presence of transients. This information is used to adjust the block size of the data transformed, restricting quantization noise associated with the transient to within a small temporal region about the transient, avoiding temporal unmasking. The method under consideration utilizes the fact that the changing data block size and/or windowing time position, occurring on compression encode, must be transmitted to the decompression decoder in order to accurately decompress the encoded audio signal. One method of doing this is through the use of side chain information, although other methods, which embed this information into the compressed audio data stream itself, may be employed. This permits the decoder to accurately synchronize the decode operation with the varying encoded data block size and assure the same block size is employed for decode as was used for encode, thus avoiding temporal unmasking. The present method takes advantage of the fact that this additional side chain information is not included in the decompressed audio data stream and is thus not available to subsequent compression processes.

To exploit this circumstance, the present method calls for the one generation compression algorithm under consideration to place transient noise or data at locations in the audio data stream being compressed which is synchronized with the sample block size and sample block timing used during the process of transforming the audio data stream data from the time to the frequency domain. This transient extraneous data is tailored such that the audio data present in the audio signal begin compressed, which occurs immediately before and immediately after the transient, masks the audibility of these transients, so they will not be perceptible to the listener when the audio signal is decompressed. In addition, the one generation compression algorithm under consideration uses a varying sample block size during the process of transforming the data from the time to the frequency domain. Data regarding this varying block size, as well as data regarding where transients were inserted into the audio stream, are transmitted to the decoder by one of several means well known in the art. This data will permit the original audio signal to be decompressed and reproduced with high quality. No transient artifacts would be heard by a listener. However, since block size and transient timing information is not included with the decompressed audio data stream, a subsequent compression process, whether it uses a fixed size window, multiple fixed sized windows or dynamically sized windows to analyzing the spectral and temporal components of the audio signal being compressed, will be unable to select the best window size for transient response, or synchronize the windowing function to the transients that were inserted in the uncompressed, treated audio stream. This will cause these transients to be temporally unmasked and therefore audible at the output of the second compression decompression cycle. This temporal masking embodiment, as the others, is advantageously implemented in the system described in the above referenced Secure Transmission Patent Application, in order to prevent the consumer from having access to the digital signals from the first compression process before they are converted to PCM or analog signals.

In a fifth example of the one generation codec embodiment, phase, timing and/or amplitude discontinuities are inserted into one or more of the channels of the encoded audio. These discontinuities are designed to be as imperceptible to the human ear as possible when they appear in the decompressed audio. However, they are tailored to cause the initiation of different compression processing modes in a subsequent encoding process, as described in the fifth example of the first anti-compression embodiment of this invention. The incorporation of these discontinuities in the codec allows for the discontinuities to be embedded in the encoded signal at the time of encoding, or the passing of discontinuity information from the encoder to the decoder by means of carrying the additional discontinuity data along with the encoded data stream in the data structure of the encoded signal.

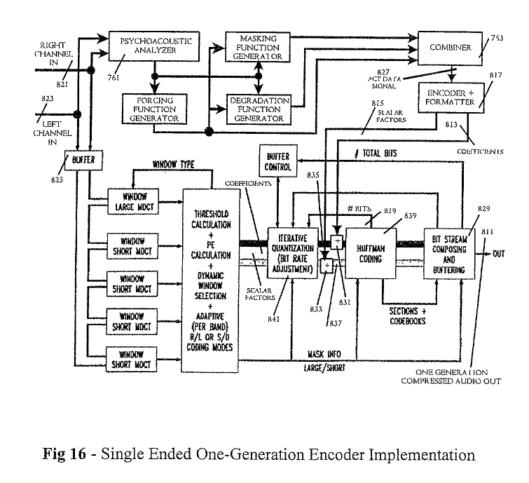

In the case where discontinuities are embedded into the encoded signal at the time of compression encoding, encoded discontinuities are added to the encoded, compressed audio data itself, such that the decompression decoder will pass these discontinuities into the decompressed data stream without acting upon them, other than to decode them and convert them from the frequency domain to the time domain. They will therefore appear in the decompressed data stream with minimal or no alteration and be difficult to perceive in the decoded data stream. However, once this decoded data stream is again compressed and subsequently decompressed, these discontinuities cause this second decoded data stream version to be degraded, as previously described, compared to the audio signal that was first encoded. FIG. 16 depicts an implementation of this unique One Generation encoder approach. A Right audio input channel 821 and a Left audio input channel 823 are simultaneously inputted into the ACT processing scheme beginning with a Psychoacoustic analyzer block 761 and ending with a Combiner block 753, and the audio compression encoding scheme beginning with a Buffer block 825 and ending with a Bit Stream Composing and Buffering block 829. The ACT processing scheme depicted in FIG. 16 is the same method previously described and depicted in FIG. 15 of the present patent specification. The audio compression encoding scheme depicted in FIG. 16 is fully described in the previously mentioned U.S. Pat. No. 5,285,498, of James D Johnston. As illustrated in FIG. 7 of the Johnston patent's specification, ACT Data Signal 827 is equivalent to ACTed Audio output 759 of FIG. 15 hereof, less the PCM Audio Input 757. As shown in FIG. 15, the ACTed Audio Output is composed of a Forcing Function 751 combined with a Masking Function 801, a Degradation Function 755 and a PCM Audio Input 757. Thus, 827 represents the ACT signal derived from the aforementioned Anti-Compression signal components before they are combined with the input signal which is undergoing Anti-Compression processing.

The ACT Data Signal 827 is then input to an Encoder and Formatter block 817 to be converted into the frequency domain and formatted such that it can be combined in Combiner blocks 831 and 833 with the transform coded and quantized version of the input audio signals appearing on lines 835 and 837. The combined encoded audio and Anti-Compression elements are then passed through Huffman Coding block 839 to losslessly remove redundant information. Note that the addition of Anti-Compression data elements, that appear on lines 815 and 813, to the encoded audio signal components that appear on lines 835 and 837, will, in general, increase the data rate of the encoded signal. Since the output data rate from the compression encoder is fixed, the increase in data rate needs to be compensated for by reducing the amount of data which comprises the encoded audio data stream itself. This compensation is effectuated by the use of Line 819, # Bits., which feeds back the combined audio and Anti-Compression data rate to an Iterative Quantization block 841. The information provided by a line 819 causes the block 841 to increase the quantization coarseness of the encoded audio signal, thereby reducing the encoded audio data rate and compensating for the additional Anti-Compression data elements that have been placed in the encoded audio signal. After Bit Stream Composing and Buffering by a block 829, the resulting encoded compressed audio signal is now in a form that can be decoded and decompressed by any appropriate decoder using techniques which are well known in the art. However, the decoded signal produced by these decoders will be unique in that the decoded audio output delivered will contain Anti-Compression elements that disallow a subsequent compression and decompression process from delivering a high quality audio experience.

It should be noted that the “single ended” one generation codec approach described above, a technique that does all anti-compression processing of the input audio signal during the encoding of the compressed audio data steam without using the decompression decoder as part of the process, is a unique concept. By permitting the deployment of decompression decoders, which are capable of playing current content, as well being able to properly reproduce One Generation compressed audio content, this methodology allows the establishment of an installed based of players and customers, before One Generation encoders and One Generation compressed audio content is generally available. For example, if one were to chose to make an MP3 compatible One Generation encoder there would be an established base of hundreds of millions of One Generation MP3 players in the field at the present time, each player capable of producing anti-compressed audio signals from One Generation MP3 encoded content.

In the case of the One Generation Codec approach, which employs the passing of Anti-Compression discontinuity information from the encoder to the decoder in the data structure of the encoded signal, not in the encoded audio data itself, the decoding and mixing of the discontinuities with the decoded data stream takes place in the decoder. This has the benefit of permitting the original, unprocessed encoded data stream to be recovered, if this should be desired, but requires that the discontinuity information be hidden in the encoded data structure so it cannot be removed before it is added to the decoded audio data. It should be noted that a decoder can be constructed such that the discontinuity data is generated as part of, or as a separate process from, the decoder, using the principles illustrated in FIG. 15, with the PCM Audio input 757 being the PCM decoded output of the decompression decoder. In this case, no discontinuity information is passed to the decoder from the encoder. The discontinuity information would be derived from analysis of the signal characteristics of the decoded audio signal and combined with the decoded audio signal before it is delivered to the user as a time domain audio output.

This one-generation approach provides compressed audio data that can be stored and distributed in any of a number of ways. The distribution of such audio data in a form for use with individual portable audio players is mentioned above. In this case, the players contain the software necessary to decompress the data. The media storing the compressed data can be any one of commercially available media, such as non-volatile semiconductor memory in the player itself or in removable cards, small rotating magnetic disk drives and small optical disks. However, it is preferred that security techniques be applied to restrict access to such compressed data in order to prevent it from being distributed in its compressed form. An audio signal decompressed from a copy of the compressed data file will have a high quality. Security techniques, such as those described in the Secure Transmission Patent Applications referenced above, are therefore desirably applied.

Another application is with the sound track of motion picture films. Sound is commonly recorded in a compressed form. Movies are often video taped during an opening theater showing of them by a member of the audience. The video tape is then used to make copies of the film that are then distributed illegally. In order to obtain a good quality sound signal, an infrared audio signal transmission that is available in many theaters for use by people who are hard of hearing is intercepted and used. This uncompressed sound signal is then recompressed for recordation on the copies. If the sound track of the film has been compressed with one of the techniques described above, however, the audio signal decompressed from the illegal copies will have an unacceptable quality.

Changing the Audio Signal Processing

Although the various example implementations of two embodiments of the present invention have been described in the form of fixed algorithms applied to an input audio signal, all of the algorithmic processes described can be adjusted during their application as a function of input audio signal characteristics. The objective of this adjustment is to maximize the difference between the processed audio signal and the processed audio signal after undergoing audio compression. This “adaptive processing”, referred to as optimization, can be effectuated by first analyzing the amplitude and timing of the input audio signal's frequency components, as well as the relationship between the audio data present in each channel of the input audio signal, and then using this information to select from a multiple of processing algorithms or to adjust process algorithm parameters and function. Changes to the phase, amplitude and frequency modifications, as well as the character of the spurious data, introduced in the treated audio signal will directly influence both the quality of the uncompressed processed audio signal and the amount the processed audio signal is degraded after compression.

The block diagram of FIG. 9 depicts anti-compression method 619 which can be used alone to add anti-compression characteristics to uncompressed audio signals or as part of a one generation audio compression codec 619 that operates on two channel stereo audio signals and tunes anti-compression processing as a function of input signal characteristics. For a monophonic implementation, only blocks 583, 585, 587, 589 and 593 of 619 would be required because the additional blocks shown, 611, 603, 601, 599, 597 and 595, are for second channel relationship analysis and second channel anti-compression processing. For a greater than two channel implementation, elements of method 619 are replicated to accommodate the processing and relationship analysis required by the additional channels. An instance of blocks 611, 603, 601, 599, 597, and 595 would be required for each additional channel added. In method 619, stereo audio channel number 1 is applied to input line 617 and stereo audio channel number 2 is applied to input line 605. These two audio signals are separated into their individual frequency components by filter bank 583 and filter bank 603 respectively. Although not depicted, the frequency component separation process would normally be digital in nature and require the input signals to first be converted to digital form, if they were not already in digital form when applied. In addition, filter banks 583 and 603 could either be transformed based, as employed by signal modification system 511, or a sub-band based. If a transform based process is employed, a block quantizing step would be required before the frequency component separation step performed by blocks 583 and 603.

The method 619 assumes the use of a sub-band based process, so no prior block quantizing step is shown. A sub-band based process uses narrow band time domain filters to continuously partition the input audio signal into its critical frequency bands. The input audio signal is therefore not transformed into its frequency domain representation and thus no block quantizing step is required. The frequency component activity analysis derived by blocks 583 and 603, which corresponds to block spectrum 533 of system 511, is used by blocks 585 and 601 respectively to calculate the masking functions associated with each of the two stereo channels as well as to derive, for example, temporal audio activity, audio signal dynamic range, and audio signal baseline offset. This information is used by spurious signal generator blocks 587 and 599 respectively, often in conjunction with data from signal relationship block 611, to create spurious signals, which are combined with the input stereo signals 617 and 605 by adder blocks 593 and 595, which are output on lines 591 and 621 as anti-compressed treated signals. It is also used by signal modification blocks 589 and 597, also often in conjunction with data from block 611, to alter, but not add to, the signals output on 591 and 621. For example, time related masking curve information from blocks 585 and 601 can be employed by blocks 587 and 599 to create noise bursts inserted into the output audio signals 591 and 621 that are optimized in both timing and in frequency characteristics, so as to maximally confuse audio compression codecs employing Huffman encoding techniques, as previously described, but which are masked by the audio signal frequency components present so they are minimally audible to the listener. Also, the frequency and phase relationships between the input audio signals appearing on line 617 and 605, that are derived by the actions of block 611, can be used by audio signal modification blocks 589 and 597 to adaptively shift the relative phase of frequency elements common to both output signals 591 and 621, so as to cause audio compression codecs employing joint stereo encoding techniques to be optimally confused, as previously described, and produce degraded results. Further, signal relationship data from block 611 can be used by blocks 587 and 599 to add out of phase extraneous signals into each of the output channels, through the use of blocks 593 and 595, that can only be heard if the stereo output signal is compressed with an audio compression codec using absolute value addition techniques, as was also previously described, thus again causing poor results from a subsequent compression/decompression process.

In a typical application of either the first or second embodiment of the present invention, each of multiple incoming audio signals is modified according to a common algorithm. In the event that a computer hacker is able to ascertain that algorithm and then use that information to remove the modifications from an audio signal, the algorithm can be changed by a content provider for subsequent audio signal processing. This would then make it necessary for the hacker to determine the new algorithm each time it is changed. Alternatively, many different algorithms can be alternately used by content providers in order to make the task of removing the modifications from the signal even more difficult. This notion can be taken one step further by using a different algorithm on different parts of the same song or other audio content. In addition to causing greater challenges for computer hackers in their efforts to compromise the beneficial effects of the audio processing begin disclosed, it will allow a single song to be tailored to the characteristics of multiple audio compression technologies and thus prevent this processed song from being compressed with quality by a large number of different compression encoder algorithms.

Electronic Measure of Perceptibility

Although it is the perception by ordinary human listeners of audio signals processed by the various techniques described above that is ultimately important, the perceptibility of the processing techniques can be measured by electronic means. In the examples of the first embodiment described above, the effect of anti-compression processing on an input audio signal before undergoing a compression step can be measured in this way. The anti-compressed processed signal is first passed through a series of bandpass filters in order to decompose this signal into the frequency components that comprise the processed audio signal. The input audio signal is also passed through a series of bandpass filters in order to decompose this signal into the frequency components that comprise the input audio signal. The unprocessed signal is subtracted from the anti-compressed processed signal to obtain the frequency components added to the input audio signal that comprise the added anti-compression signal. The added anti-compression signal is then compared, by use of a spectrum analyzer, with well known human hearing masking curves, which are used in all perceptual compression encoders, to determine the audibility of the applied anti-compression signal as it appears in the anti-compressed version of the original audio signal.

The effect of the processing in the examples of the second embodiment described above can also be measured by electronic techniques. The effect is a measure of anti-compression processing on a decompressed audio signal derived from an input audio signal that has undergone anti-compression processing and a compression encoding step. Discontinuities in the decompressed audio data stream are analyzed, where the decompressed audio data stream is derived from an input audio signal that has undergone anti-compression processing and a compression encoding step. The compressed audio data stream is frequency decomposed by using a series of bandpass filters. The average energy is measured, on a frequency bin basis, of the decompressed audio data stream under test. The deviations from these average energy values are then measured at the times at which anti-compression elements were added to the input, uncompressed, audio data stream. These energy variations are then electronically compared, on a frequency bin basis, with well known human masking curves, by means of an audio spectrum analyzer, to determine a measure of the audibility of the anti-compression signal included in the output decompressed signal.

Video and Other Applications

The techniques of processing digital signal files has been described above for use with audio signals. The protection of the transmission and sharing of audio content is currently a big concern, primarily because of the ease with which such content can be distributed over the Internet and on physical storage media. But the same approaches can also be applied to reduce the incentive to copy or transfer other types of data files, when that becomes desirable. Commercial movies and other video content is an example of content that can be similarly processed. Although the transmission of compressed video data files over the Internet and other communications networks is not now widespread because the bandwidth requirements exceed that available from the communications networks, this is likely to change in the future.

Since most video, when in a digital form, is compressed, the techniques of the second embodiment described above for compressing audio data can also be used when compressing the video data. Although the compression and decompression algorithms are necessarily different, their characteristics are similar to those used with sound. A decompressed video signal, such as one obtained from a DVD disc, cannot be satisfactorily copied and again compressed since the decompressed video signal will have high levels of noise and distortion that makes the video unpleasant for a viewer to watch. This is especially the case when the video image repeatedly switches between a reasonably good image and a very poor image, or between two levels of poor images.

Conclusion

The present invention is fundamental to the processing of either original or compressed signals to make them unsuitable for any further compression. The invention is particularly suitable for use with signals that are interfaced with humans, such as audio, particularly music, and video signals, since the poor quality of unauthorized copies will not be tolerated by humans. Although the various aspects of the present invention have been described with respect to specific embodiments and examples thereof, it will be understood that the invention is entitled to protection within the full scope of the appended claims.

It is claimed:

1. A method of processing a human interface signal, comprising modifying the interface signal in a manner minimizing the perceptibility of the modification when the interface signal is reproduced but which modifies the signal sufficiently so that a reduced quality is perceptible in a signal reproduced from a compressed version of the modified signal upon its decompression.

2. The method of claim 1, wherein the interface signal is a audio signal and the reproduced signal is a sound signal.

3. The method of claim 2, wherein modifying the audio signal includes increasing levels of certain frequency components of the audio signal.

4. The method of claim 2, wherein modifying the audio signal includes ascertaining spectral distributions of temporally successive blocks of data of the audio signal, determining masking functions for individual ones of the spectral distributions of data, an individual masking function defining upper levels of frequency components of its associated block of data to which perception of the signal does not change, and increasing the levels of at least some of the frequency components of the spectral distributions below their respective masking functions.

5. The method of claim 2, wherein the audio signal includes at least first and second channel signals , and wherein modifying the signal includes altering a relationship between said at least first and second channel signals.

6. The method of claim 5, wherein altering relationships includes altering amplitude, timing or phase relationships between said at least first and second channel signals.

7. The method of claim 5, wherein modifying the audio signal additionally includes utilizing the relationship between said at least first and second channel signals to unmask components of the audio signal that are masked.

8. The method of claim 2, wherein modifying the audio signal further includes doing so in a manner which causes a sound data compression and decompression algorithm, when compressing the modified audio signal, to at least part of the time invoke at least one compression mode that is different from that which is invoked by the audio signal alone in order that the compressed version thereof results in a version of the audio signal that is perceptible upon its decompression to be undesirably changed.

9. The method of claim 8, wherein modifying the audio signal further includes doing so in a manner which causes the compression and decompression algorithm to compress the modified audio signal by invoking said at least one algorithm compression mode that is alternately the same and different from that which is invoked by the original audio signal alone.

10. The method of claim 8, wherein the audio signal includes two or more audio channels and the sound data compression and decompression algorithm includes at least two compression modes, a first mode wherein data of each of the two or more channels of the audio signal are compressed separately and a second mode wherein data of the audio signal of the two or more channels are combined together prior to compression.

11. The method of claim 2, wherein modifying the audio signal includes non-continuously removing at least one component from the audio signal.

12. The method of claim 2, additionally comprising initially decompressing the audio signal from a compressed version thereof received over a communications network, the initial decompression and the modification of the decompressed audio signal being carried out in a processor unit that isolates the decompressed audio signal from a user prior to its modification.

13. The method of any one of claims 1-12, additionally comprising recording the modified signal in a physical storage medium.

14. The method according to claim 1, wherein modifying the signal additionally includes doing so in a manner that also minimizes the perceptibility of the modification when the signal is compressed and decompressed a first time but wherein said reduced quality is perceptible in the signal when reproduced from a decompression of the second compression of the signal.

15. The method of claim 14, wherein the interface signal is a audio signal and the reproduced signal is a sound signal.

16. The method of claim 15, wherein modifying the audio signal includes adding noise or audio data thereto.

17. The method of claim 16, wherein the noise or audio data is added to the audio signal in recurring bursts.

18. The method according to any one of claims 14-17, additionally comprising recording the signal in a first compressed version thereon in a physical storage medium.

19. A method of compressing a human interface signal, comprising modifying a process of its compression in a manner that minimizes the perceptibility of a resulting change to the signal when decompressed from said compression but which results in a second signal having a reduced quality when reproduced from a second compression and decompression of the decompressed audio signal.

20. The method of claim 19, wherein the interface signal is a audio signal and the second signal is a sound signal.

21. The method of claim 20, wherein modifying the compression process includes altering timing of processing of defined time sequential blocks of data of the audio signal.

22. The method of claim 20, wherein modifying the compression process includes doing so as a function of at least one characteristic of the audio signal.

23. The method of claim 20, wherein modifying the compression process includes using a quantizer adjusted to quantize individual frequency components of the audio signal in a manner that avoids the perceptibility of quantizing errors in the audio signal when decompressed from said compression but which renders quantizing errors perceptible in a sound signal reproduced from the second compression and decompression of the decompressed audio signal.

24. The method of claim 20, wherein modifying the compression process includes adding encoded discontinuities to data resulting from compression of the audio signal.

25. The method of claim 24, wherein the encoded discontinuities are characterized by invoking at least part of the time in a second compression at least one compression mode that is different from that which is invoked without the discontinuities.

26. The method of claim 25, wherein the encoded discontinuities are further characterized by intermittently invoking said at least one compression mode.

27. The method of any one of claims 19-26, additionally comprising recording the compressed signal in a physical storage medium.

28. An audio signal in a form allowing reproduction thereof, comprising audio content that has been modified in a manner minimizing the perceptibility of the modification when the audio signal is reproduced but which causes the audio content to have a reduced quality when the audio signal is compressed and decompressed.

29. The audio signal according to claim 28, wherein the modifications of the audio content include increased levels of certain frequency components of the audio content below making levels.

30. The audio signal according to claim 28, wherein the modifications of the audio content are characterized by causing a sound compression and decompression algorithm to compress the audio signal at least part of the time by invoking at least one compression mode that is different than that which would be invoked by the audio content alone.

31. The audio signal according to claim 30, wherein the modifications of the audio content are further characterized by causing the compression and decompression algorithm to intermittently invoke said at least one different compression mode.

32. The audio signal according to claim 28, wherein the audio signal includes a single audio selection, title, song or portion thereof.

33. The audio signal of any one of claims 28-32 stored on a physical storage medium.

34. The audio signal of claim 33, wherein the physical storage medium is selected from a group consisting of a magnetic storage device including a computer disk or an audio tape cassette, an optical storage device including a Compact Disc or a Digital Video Disc, motion picture film and a non-volatile semiconductor memory card.

35. A compressed version of an audio signal in a form allowing decompression and reproduction thereof, comprising a compressed version of audio content that has been modified in a manner minimizing the perceptibility of the modification when the audio signal is decompressed but which causes the audio content to have a reduced quality when the decompressed audio signal is compressed and decompressed for a second time.

36. The compressed audio signal according to claim 35, wherein the compressed audio signal is characterized by invoking at least part of the time in a second compression of the decompressed audio signal at least one compression mode that is different from that which is invoked without the modification to the audio content.

37. The compressed audio signal according to claim 36, wherein the compressed audio signal is further characterized by intermittently invoking the different compression mode in a second compression.

38. The audio signal according to claim 35, wherein the audio signal includes a single audio selection, title, song or part thereof.

39. The audio signal of any one of claims 35-38 stored on a physical storage medium.

40. The audio signal of claim 39, wherein the physical storage medium is selected from a group consisting of a magnetic storage device including a computer disk or an audio tape cassette, an optical storage device including a Compact Disc or a Digital Video Disc, motion picture film and a non-volatile semiconductor memory card.

41. A signal processing device, comprising a memory and a processor controlled to modify an encrypted compressed input audio content signal to produce an unencrypted decompressed output signal with modifications selected to not be perceived but which, if the output signal were to be compressed and then decompressed a second time, would generate a second decompressed signal of poor quality, the processor and memory being protected to prevent a user from having ready access to an unencrypted version of said signal without said modifications.

42. A signal processing device, comprising a memory and a processor controlled to unencrypt and decompress an encrypted compressed input audio signal that has been processed so that an unencrypted decompressed output signal therefrom carries modifications selected to not be perceived but which, if the output signal were to be compressed and then decompressed a second time, would generate a second decompressed signal of poor quality, the processor and memory being protected to prevent a user from having ready access to an unencrypted version of said signal without said modifications.

43. The signal processing device of either one of claims 41 or 42, wherein the module is in the form of a card that is removably insertable into a sound reproducing device.

44. A system for processing an input audio signal to generate a modified version thereof as an output audio signal, comprising:
an analyzer receiving the input signal that determines acoustic elements of the input signal,
a function generator that receives the input signal acoustic elements and generates a function in response thereto that, when combined with the input signal, generates the output signal that is perceptively substantially the same as the input signal but which, when compressed and decompressed, would produce a sound signal that is perceptively significantly inferior to the input signal, and
a combiner of the input signal and the function that provides the output audio signal.

45. The system of claim 44, wherein the function generator includes a degradation function generator that modifies the input signal in a manner that the degradation would be perceptible in said sound signal.

46. The system of claim 44, wherein the function generator includes a forcing function generator that would cause an algorithm compressing the output signal to operate in an incorrect mode at least part of the time.

47. The system of any one of claims 45 or 46, wherein the function generator includes a masking function generator that operates in response to the acoustic elements of the input signal to reduce the perceptibility of the generated function in the output signal prior to any compression thereof.

48. An audio signal processing system, comprising:
an audio data compressor that receives an input audio signal and generates a compressed version thereof as an output audio signal,
an analyzer receiving the input signal that determines acoustic elements of the input signal,
a function generator that receives the input signal acoustic elements and generates a function in response thereto that, when inserted into the data compressor, causes the output signal from the data compressor to allow a sound signal to be decompressed therefrom that is perceptively substantially the same as the input signal but which, when compressed and decompressed a second time, would produce a second sound signal that is perceptively significantly inferior to the input signal, and
an inserter of the function into the data compressor.

49. The system of claim 48, wherein the function generator includes a degradation function generator that modifies the input signal in a manner that the degradation would be perceptible in said second sound signal.

50. The system of claim 48, wherein the function generator includes a forcing function generator that would cause an algorithm compressing the output signal a second time to operate in an incorrect mode at least part of the time.

51. The system of any one of claims 49 or 50, wherein the function generator includes a masking function generator that operates in response to the acoustic elements of the input signal to reduce the perceptibility of the generated function in the sound signal.
